(19) United States
(12) Patent Application Publication
(10) Pub. No.: US 2024/0292526 A1
(43) Pub. Date: Aug. 29, 2024

(54) Flexible printed circuit

(71) Applicant: AAC Microtech (Changzhou) Co., Ltd., Changzhou (CN)

(72) Inventor: Zhigao Lu, Changzhou (CN)

(21) Appl. No.: 18/337,423

(22) Filed: Jun. 19, 2023

(30) Foreign Application Priority Data
Feb. 28, 2023 (CN) 202320345262.6

(51) Int. Cl. H05K 1/02

(52) U.S. Cl. CPC H05K 1/0277; H05K 1/0296; H05K 3/28; H05K 2201/0154; H05K 2201/0376

(57) ABSTRACT

The present disclosure discloses a circuit board including a substrate layer, a line layer fixed to the substrate layer and two protective layers wrapped on both sides of the substrate layer to cover the line layer, wherein, the line layer is embedded in the substrate layer and the surface of the line layer is flush with the surface of the substrate layer. The surface of the flexible circuit board is neat and can be easily bonded to other components, and during processing, because the surface of the line layer and the substrate layer are flush, when the protective layer is laminated to the substrate layer, there is no gap between the protective layer and the substrate layer, and the protective layer and the line layer, so there are no cavity bubbles between the line layer and the protective layer, and it has a high thermal reliability level.

### FIELD OF THE PRESENT DISCLOSURE

The present disclosure relates to circuit boards, especially relates to a flexible printed circuit.

### DESCRIPTION OF RELATED ART

Flexible Printed Circuit (FPC), also known as flexible circuit board, which has a light quality, thin thickness, can be freely bent and folded and other excellent features and is widely used in electronic computers, automation instruments or communication equipments, etc. . . . The current flexible circuit board for single-sided or double-sided copper foil, made by the subtractive process, copper lines raised on the substrate PI, the adhesive layer filling the gap when pressed cover film, however, the surface of the flexible circuit board prepared in this way is raised and uneven, on the one hand, will cause the surface of the flexible circuit board is not easy to bond other components, on the other hand, the adhesive layer-copper interface will have the risk of hollow bubbles.

Therefore, it is necessary to provide a new kind of flexible circuit board.

### SUMMARY OF THE INVENTION

The present disclosure provides a flexible printed circuit capable of making the surface of the flexible printed circuit flat, easy to bond other components and without the risk of cavities and bubbles.

The flexible printed circuit comprising a substrate layer, a line layer fixed to the substrate layer and two protective layers wrapped on both sides of the substrate layer to cover the line layer, wherein, the line layer is embedded in the substrate layer and the surface of the line layer is flush with the surface of the substrate layer.

Further, the substrate layer is a light-sensitive overlay film.

Further, the protective layer includes an insulating layer located on one side of the substrate layer, and a adhesive layer fixed between the insulating layer and the substrate layer and connecting the insulating layer and the substrate layer as one.

Further, the material of the insulating layer is PI material.

Further, the surface of the insulating layer on a side away from the substrate layer is a flat plane.

Further, the adhesive layer is fully laminated to the substrate layer and the line layer.

Further, the substrate layer has a cavity through the substrate layer, the line layer being completely filled within the cavity.

Further, the material of the line layer is copper.

In the flexible printed circuit of the present disclosure, the line layer is embedded in the substrate layer, and the surface of the line layer is flush with the surface of the substrate layer, and the protective layer wraps around the substrate layer and the line layer, so the surface of the flexible circuit board in this disclosure is neat and can be easily bonded to other components, and during processing, because the surface of the line layer and the substrate layer are flush, when the protective layer is laminated to the substrate layer, there is no gap between the protective layer and the substrate layer, and the protective layer and the line layer, so there are no cavity bubbles between the line layer and the protective layer, and it has a high thermal reliability level.

### BRIEF DESCRIPTION OF THE DRAWINGS

The present disclosure will hereinafter be described in detail with reference to an exemplary embodiment. To make the technical problems to be solved, technical solutions and beneficial effects of present disclosure more apparent, the present disclosure is described in further detail together with the figures and the embodiment. It should be understood the specific embodiment described hereby is only to explain this disclosure, not intended to limit this disclosure.

FIG. 1 is a cross-sectional view of the flexible printed circuit of the present disclosure.

FIG. 2 is a process flow diagram of the flexible printed circuit of the present disclosure.

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

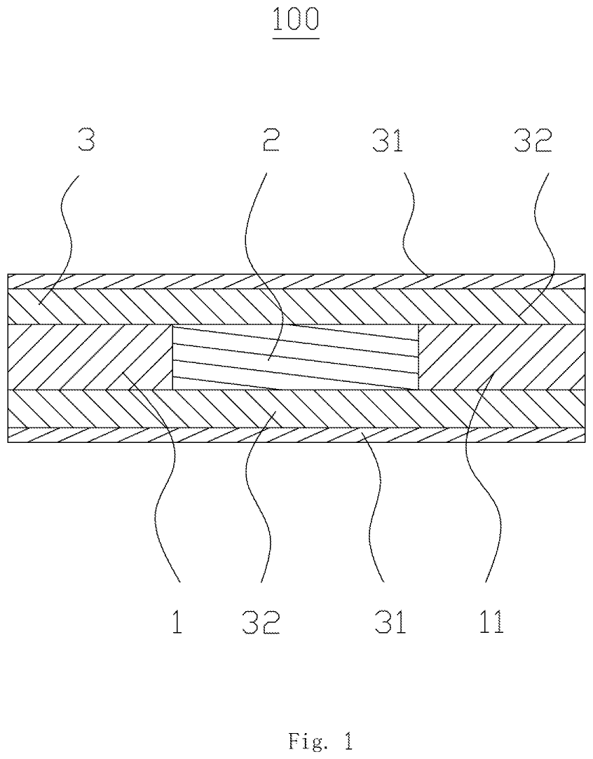

Please refer to FIG. 1, a flexible printed circuit 100 comprising: a substrate layer 1, a line layer 2 fixed to the substrate layer 1 and two protective layers 3 wrapped on both sides of the substrate layer 1 to cover the line layer 2, wherein, the line layer 2 is embedded in the substrate layer 1 and the surface of the line layer 2 is flush with the surface of the substrate layer 1. Specifically, the substrate layer 1 has a cavity 10 through the substrate layer 1, the line layer 2 being completely filled within the cavity 10.

The flexible printed circuit 100 of the disclosure, the line layer 2 is embedded in the substrate layer 1 and the surface of the line layer 2 is flush with the surface of the substrate layer 1, the protective layer 3 is wrapped around the substrate layer 1 and covered with the line layer 2. So the surface of the flexible circuit board in this disclosure is neat and can be easily bonded to other components, and during processing, because the surface of the line layer 2 and the substrate layer 1 are flush, when the protective layer 3 is laminated to the substrate layer 1, there is no gap between the protective layer 3 and the substrate layer 1, and the protective layer 3 and the line layer 2, so there are no cavity bubbles between the line layer 2 and the protective layer 3, and it has a high thermal reliability level.

Referring further to FIG. 1, the substrate layer 1 is a light-sensitive overlay film 11.

For example, a light sensitive overlay film 11 is obtained by preparing a light sensitive compound into a light sensitive adhesive and then coating it on a polymer substrate layer and curing it.

Among them, the polymer substrate layer is polyimide (PI) film, including two types of homogeneous polyimide film and biphenyl polyimide film. Where homophthalic polyimide films are made from homophthalic tetracarboxylic anhydride and diaminodiphenyl ether, and biphenyl polyimide films are made from biphenyl tetracarboxylic dianhydride and diphenyl ether diamine (type R) or from formic dianhydride and m-phenylenediamine (type S). Polyimide materials are non-flammable, geometrically stable, have high tear strength, and have the ability to withstand welding temperatures. In other embodiments, the polymer substrate layer can be polyester (PET: Polyester) film, which is a film made from polyethylene terephthalate, extruded into a thick sheet, and then stretched. The physical properties of polyester film are similar to those of polyimide and have a low dielectric constant.

The light sensitive adhesive layer is obtained by curing the light sensitive compound (carboxylated resin polymer, alkali soluble resin, photoinitiator, metal ion source and reducing agent). The carboxylate produced by the carboxylated resin polymer interacts chemically with the metal ions in the metal ion source through coordination, and the alkali-soluble resin helps to synergistically promote the coordination of the carboxylate with the metal ions in the metal ion source, thus better anchoring the metal ions more uniformly in the photopolymer layer. This in turn ensures that the metal ions in the metal ion source are concentrated and loaded on a certain resin carrier during exposure development by UV light irradiation; the alkali-soluble resin is cured to a higher molecular weight polymer under photoinitiator as well as light conditions, thus contributing to the strength of the light sensitive overlay film 11.

Wherein the weight ratio of the carboxylated resin polymer to the metal ion source may be 3:2 to 3:1, which is conducive to improving the immobilization of the metal ions in the metal ion source with the carboxylated resin polymer; the carboxylated resin polymer may be polyurethane or carboxylated polyamideimide, thus facilitating the concentration of the metal ion source as much as possible and thus contributing to the formation of a strongly conductive thin layer of conductive metal; the metal ion source can be any of the water-soluble copper salts, water-soluble palladium salts or water-soluble nickel salts, which are more reactive and thus can be more easily reduced; the alkali-soluble resin is a bisphenol-type epoxy resin, which has good heat and chemical resistance and does not affect the flexibility of the film; the photoinitiator can be isopropylthioxanthone or benzophenone, which can improve the polymerization efficiency of alkali-soluble resins; the reducing agent can be sodium borohydride or vitamin C. Sodium borohydride or vitamin C has a better reducing ability, and no harmful substances affecting the electrical conductivity will remain after the reduction.

Referring further to FIG. 1, the protective layer 3 includes an insulating layer 31 located on one side of the substrate layer 1, and a adhesive layer 32 fixed between the insulating layer 31 and the substrate layer 1 and connecting the insulating layer 31 and the substrate layer 1 as one. The adhesive layer 32 is fully laminated to the substrate layer 1 and the line layer 2, the surface of the insulating layer 31 on a side away from the substrate layer 1 is a flat plane.

Specifically, the insulating layer 31 is PI material, and the adhesive layer 32 is solvent-based high-elastic polyurethane, water-based high-elastic polyurethane or UV protective adhesive, which has the advantages of softness, good bending, good wear resistance, not easy to scratch, not easy to have creases, etc. Add insulating protection layer 3 on both sides of the line layer 2, can play a role in protecting the line layer 2 and increasing the strength of the substrate layer 1.

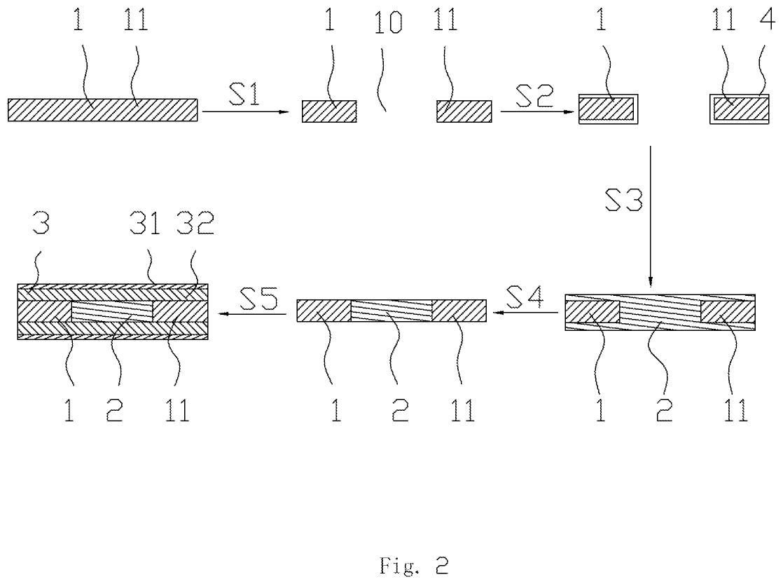

Further, see FIGS. 1 and 2, the flexible printed circuit is made after the substrate layer 1 exposure development, metallization, copper plating, copper reduction and pressure protection layer 3 in turn.

Specifically, the process of preparing the flexible printed circuit of this solution comprises the steps of:

S1, Exposure development of the light-sensitive overlay film 11 is performed to obtain the corresponding pattern of the line layer 2.

S2, PI metallization is performed on the light sensitive overlay film 11 after exposure development so that the exposed outer surface on the light sensitive overlay film 11 is uniformly covered by the metal layer 4.

S3, the metalized light sensitive overlay film 11 has copper line layer 2 deposited on both sides of the surface, and the gap of the light sensitive overlay film 11 is filled with uniform copper line layer 2 to obtain a line board with a certain thickness.

S4, copper-plated circuit board for copper reduction process, through copper reduction so that the surface of the line layer 2 and the surface of the substrate layer 1 flush.

S5, the circuit board after copper reduction and the protective layer 3 pressed together, and finally get a flexible printed circuit. Adding the insulating protective layer 3 to the circuit board can both protect the line layer 2 and increase the strength of the substrate layer 1.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A flexible printed circuit comprising: a substrate layer, a line layer fixed to the substrate layer and two protective layers wrapped on both sides of the substrate layer to cover the line layer, wherein, the line layer is embedded in the substrate layer and the surface of the line layer is flush with the surface of the substrate layer.

2. The flexible printed circuit as described in claim 1, wherein the substrate layer is a light-sensitive overlay film.

3. The flexible printed circuit as described in claim 1, wherein the protective layer includes an insulating layer located on one side of the substrate layer, and a adhesive layer fixed between the insulating layer and the substrate layer and connecting the insulating layer and the substrate layer as one.

4. The flexible printed circuit as described in claim 3, wherein the material of the insulating layer is PI material.

5. The flexible printed circuit as described in claim 3, wherein the surface of the insulating layer on a side away from the substrate layer is a flat plane.

6. The flexible printed circuit as described in claim 3, wherein the adhesive layer is fully laminated to the substrate layer and the line layer.

7. The flexible printed circuit as described in claim 1, wherein the substrate layer has a cavity through the substrate layer, the line layer being completely filled within the cavity.

8. The flexible printed circuit as described in claim 1, wherein the material of the line layer is copper.
